(19) United States
(12) Patent Application Publication
(10) Pub. No.: US 2011/0058132 A1
(43) Pub. Date: Mar. 10, 2011

(54) DISPLAY DEVICE AND MANUFACTURING METHOD THEREOF

(75) Inventors: Chien-Liang Wu, Tainan County (TW); Kuan-Hsu Fan-Chiang, Tainan County (TW); Chun-Hao Su, Tainan County (TW)

(73) Assignee: Himax Display, Inc., Tainan County (TW)

(21) Appl. No.: 12/556,855

(22) Filed: Sep. 10, 2009

(51) Int. Cl. G02F 1/1337; H01L 21/50

(52) U.S. Cl. 349/124; 438/28; 257/E21.499

(57) ABSTRACT

A manufacturing method of a display device is provided. Firstly, an active device array substrate having an active surface is provided. Next, a first patterned photoresist layer is formed on the active surface. Then, a first alignment layer is obliquely vapor-deposited on the active surface and the first patterned photoresist layer, wherein the active surface comprises at least a first undeposited area located beside an edge of the first patterned photoresist layer. A first alignment unit is formed by removing the first patterned photoresist layer and a portion of the first alignment layer located thereon. A sealant is directly formed on the active surface of the active device array substrate and surrounds the first alignment unit. An opposite substrate having a light transmissive surface is provided. After that, the active device array substrate and the opposite substrate are assembled. A display device is also provided.

### BACKGROUND OF THE INVENTION

1. Field of the Invention

The present invention relates to an optical device and a manufacturing method thereof, and more particularly to a display device and a manufacturing method thereof.

2. Description of Related Art

A liquid crystal on silicon (LCOS) panel is a display panel manufactured by using a silicon wafer as a substrate. Here, a metal-oxide-semiconductor (MOS) transistor is utilized to replace a thin film transistor (TFT) disposed on a glass substrate in a conventional transmissive LCD panel. The LCOS panel is a reflective display panel, and a pixel electrode thereof is manufactured with a non-light-transmissive metal material. Moreover, since the metal pixel electrode almost covers the entire pixel area, when comparing to a transparent pixel electrode of the conventional transmissive LC panel only capable of covering a relatively small portion of the pixel area, the LCOS panel can utilize a light source more efficiently to enhance a brightness of a display frame.

The LCOS panel is mainly constituted by the silicon substrate, a patterned metal electrode layer, and a plurality of optical film layers such as, an alignment layer, a liquid crystal layer, an alignment layer, an indium tin oxide (ITO) layer, and a glass substrate sequentially disposed on the silicon substrate. Herein, the patterned metal electrode layer is configured to constitute the pixel electrodes and the ITO layer is configured to constitute the transparent electrodes. A light from the light source passes through the glass substrate, the ITO layer, the alignment layer, the liquid crystal layer, the alignment layer sequentially to transmit to the patterned metal electrode layer. The patterned metal electrode layer reflects the light, so that the light passes through the alignment layer, the liquid crystal layer, the alignment layer, the ITO layer, and the glass substrate sequentially to transmit to the external environment.

Generally, an assembly of the LCOS panel usually adopts a sealant to adhere the silicon substrate and the glass substrate. The sealant is directly disposed on opposite surfaces of two alignment layers and surrounds the liquid crystal layer. Since a material of the alignment layer most adopts silicon dioxide having a loose molecular structure, the assembled LCOS panel is easily infiltrated by moisture into the liquid crystal layer via the alignment layer. Hence, not only is the aging of devices in the LCOS panel increased to further cause a decrease in the lifetime of devices manufactured, but the display quality and reliability of the LCOS panel is also affected.

### SUMMARY OF THE INVENTION

The present invention is directed to a manufacturing method of a display device capable of solving a conventional problem of moisture invading into a liquid crystal layer via an alignment layer, thereby enhancing a manufacturing yield rate.

The present invention is directed to display device having superior reliability and display quality.

The present invention further provides a manufacturing method of a display device. Firstly, an active device array substrate having an active surface is provided. Next, a first patterned photoresist layer is formed on the active surface. Then, a first alignment layer is obliquely vapor-deposited on the active surface and the first patterned photoresist layer, wherein the active surface comprises at least a first undeposited area located beside an edge of the first patterned photoresist layer. A first alignment unit is formed by removing the first patterned photoresist layer and a portion of the first alignment layer located thereon. A sealant is directly formed on the active surface of the active device array substrate and surrounds the first alignment unit. An opposite substrate having a light transmissive surface is provided. After that, the active device array substrate and the opposite substrate are assembled.

The present invention is further directed to a display device including an active device array substrate, an opposite substrate, at least a first alignment unit, at least a second alignment unit, a liquid crystal layer, and a sealant. The active device array substrate has an active surface. The opposite substrate is disposed above the active device array substrate and includes a light transmissive surface. Additionally, the active surface and the light transmissive surface face each other. The first alignment unit is disposed on the active device array substrate and located on the active surface. The second alignment unit is disposed on the opposite substrate and located on the light transmissive surface. Here, the first alignment unit aligns with the second alignment unit. The liquid crystal layer is disposed between the first alignment unit and the second alignment unit. The sealant directly connects the active surface of the active device array substrate and the light transmissive surface of the opposite substrate, and surrounds peripherals of the liquid crystal layer, the first alignment unit, and the second alignment unit.

In light of the foregoing, in the manufacturing method of the display device of the embodiment of the present invention, the oblique vapor-deposition is adopted in corporation with using the photoresist remover to remove the patterned photoresist layer and a portion of the alignment layer located on the patterned photoresist layer from the edge. Therefore, the alignment units are manufactured on the active device array substrate and the opposite substrate. Consequently, when the active device array substrate and the opposite substrate are connected, the sealant surrounds the peripheral of the liquid crystal layer and the alignment units. That is, the sealant is located on the active device array substrate and the opposite substrate and surrounds the liquid crystal layer and the alignment units, thereby preventing the conventional problem of moisture invading into the liquid crystal layer via the alignment layer and also enhancing the manufacturing yield rate. Hence, the display device of the embodiment of the present invention has superior display quality.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a display device according to an embodiment of the present invention.

FIG. 2A through FIG. 2J are schematic cross-sectional views of a manufacturing method of a display device according to an embodiment of the present invention.

FIG. 3A through FIG. 3C are cross-sectional views of a partial manufacturing method of a display device according to another embodiment of the present invention.

### DESCRIPTION OF EMBODIMENTS

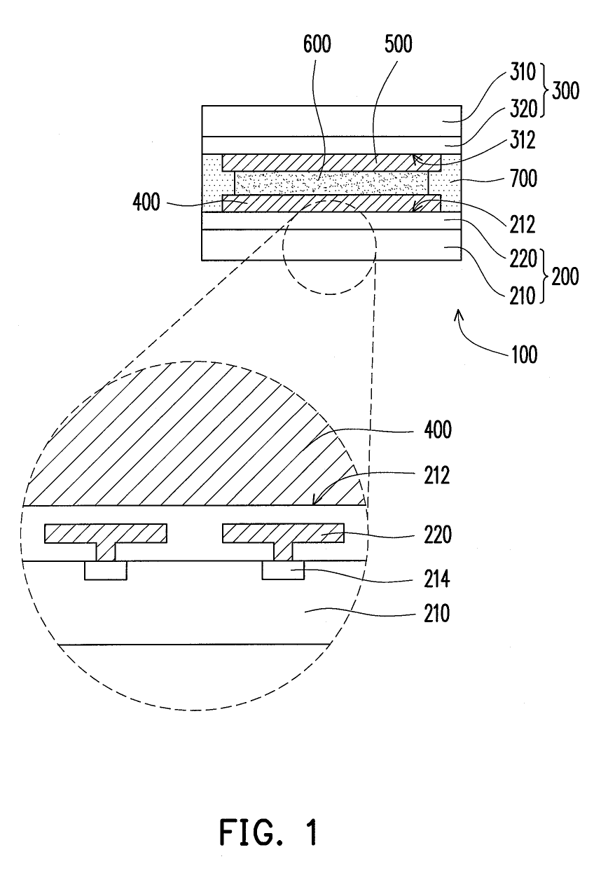

FIG. 1 is a schematic cross-sectional view of a display device according to an embodiment of the present invention. Referring to FIG. 1, an display device 100 of the present embodiment includes an active device array substrate 200, an opposite substrate 300, at least a first alignment unit 400 (only one is schematically shown in FIG. 1 for example), at least a second alignment unit 500 (only one is schematically shown in FIG. 1 for example), a liquid crystal layer 600, and a sealant 700. The display device 100 is a reflective type liquid crystal panel, for example.

The active device array substrate 200 includes a silicon substrate 210 and a pixel electrode 220. The silicon substrate 210 includes an active surface 212 and a plurality of active devices 214. The pixel electrode 220 is disposed on the silicon substrate 210 and located on the active surface 212. In the present embodiment, the active devices 214 are arranged in an array on the active surface 212 of the silicon substrate 210. The active devices 214 are transistors or other suitable active devices, for instance. A material of the pixel electrode 220 is aluminum, for example. In addition, the first alignment unit 400 is disposed on the active device array substrate 200 and located on the active surface 212 of the silicon substrate 210. Here, a material of the first alignment unit 400 is silicon dioxide, for example. Specifically, the first alignment unit 400 is disposed on the silicon substrate 210 and covers the pixel electrode 220.

The opposite substrate 300 is disposed above the active device array substrate 200 and includes a light transmissive substrate 310 and a light transmissive electrode 320. The opposite substrate 310 has a light transmissive surface 312 and the light transmissive electrode 320 is disposed on the light transmissive substrate 310 and located at the light transmissive surface 312. In the present embodiment, the active surface 212 of the silicon substrate 210 and the light transmissive surface 312 of the light transmissive substrate 310 face each other. The light transmissive substrate 310 is a fused silica substrate, a glass substrate, or a light transmissive substrate of other materials, for instance. A material of the light transmissive electrode 320 is indium tin oxide (ITO), indium zinc oxide (IZO), or other transparent conductive materials. Moreover, the second alignment unit 500 is disposed on the opposite substrate 300 and located on the light transmissive surface 312 of the light transmissive substrate 310. The first alignment unit 400 aligns with the second alignment unit 500. A material of the second alignment unit 500 is silicon dioxide, for example. Specifically, the second alignment unit 500 is disposed on the light transmissive substrate 310 and covers the light transmissive electrode 320.

The liquid crystal layer 600 is disposed between the first alignment unit 400 and the second alignment unit 500. Here, the first alignment unit 400 disposed between the liquid crystal layer 600 and the active device array substrate 200 may vertically align the liquid crystal layer 600. The second alignment unit 500 disposed between the liquid crystal layer 600 and the opposite substrate 300 may vertically align the liquid crystal layer 600.

In the present embodiment, the sealant 700 is disposed on the active device array substrate 200 and the opposite substrate 300, and directly connects with each other. Further, the sealant 700 is surrounds the liquid crystal layer 600, the first alignment unit 400, and the second alignment unit 500. Therefore, external moisture cannot infiltrate into the display device 100. In other words, the sealant. 700 effectively blocks external moisture, and thereby solving the conventional problem of moisture invading into the liquid crystal layer. Consequently, the display device 100 of the present embodiment has superior display quality.

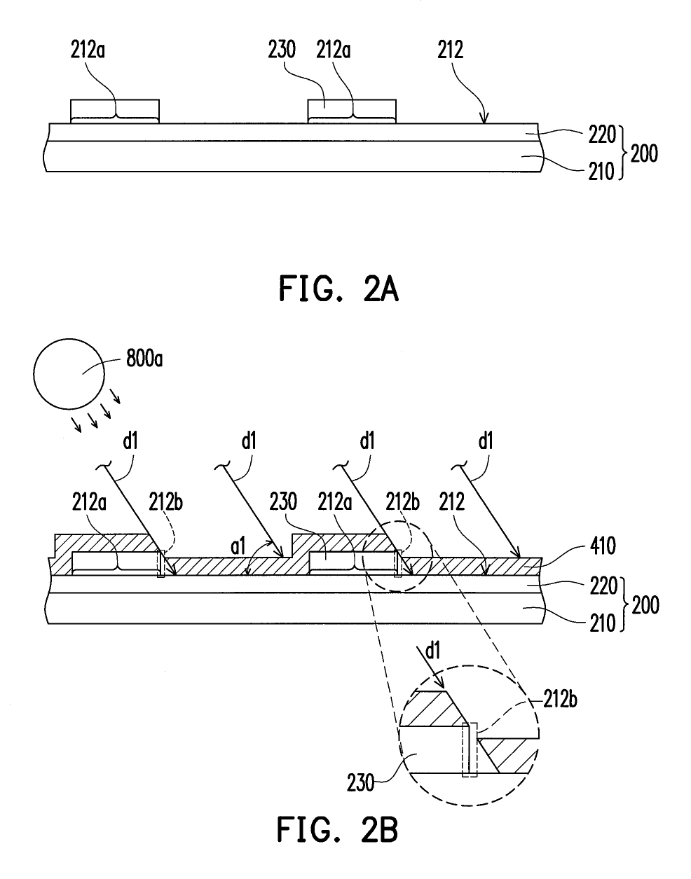

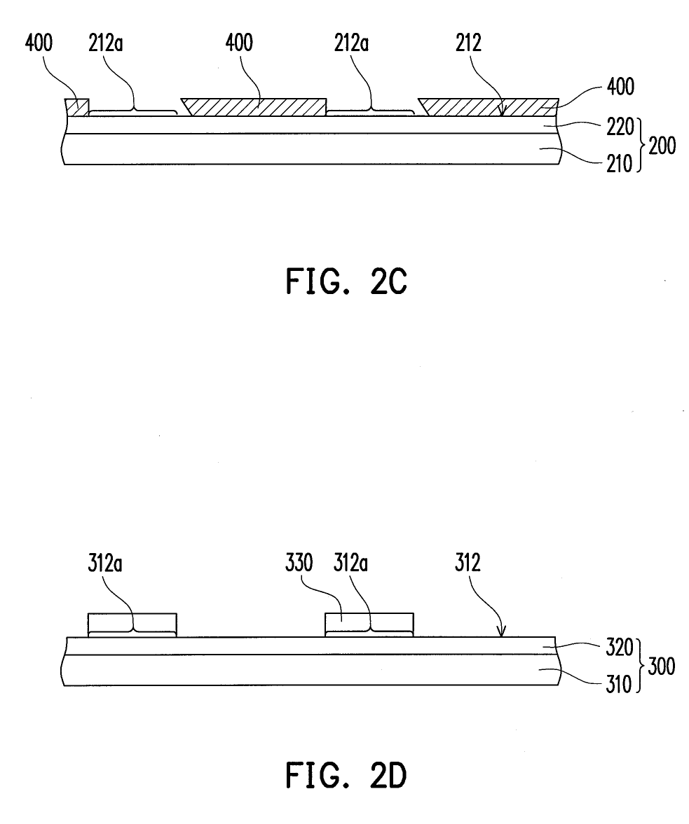

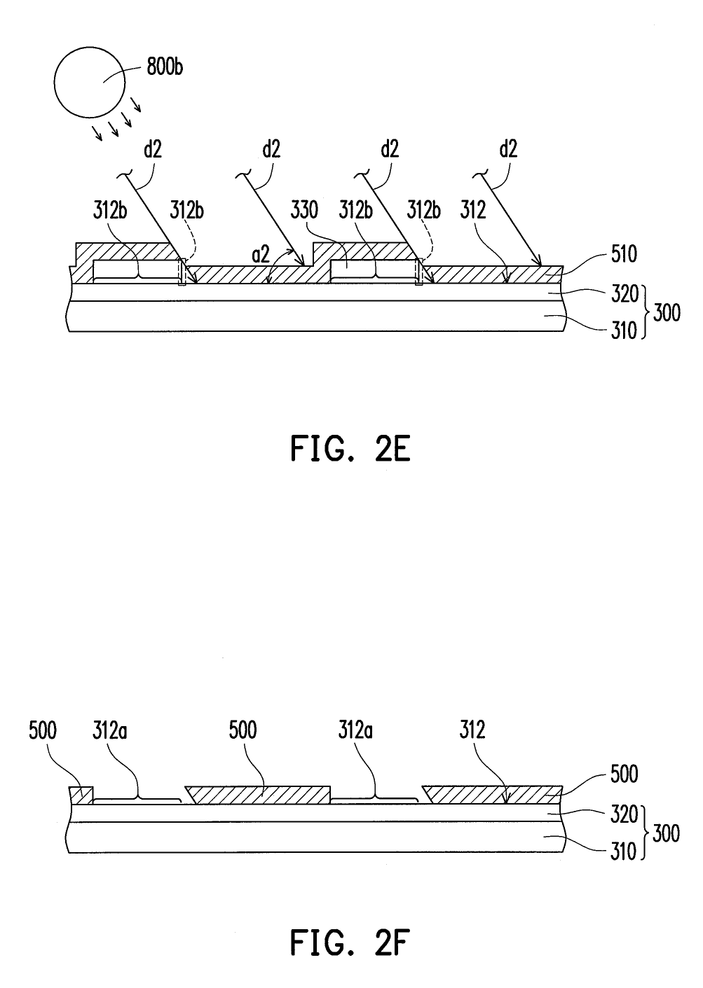

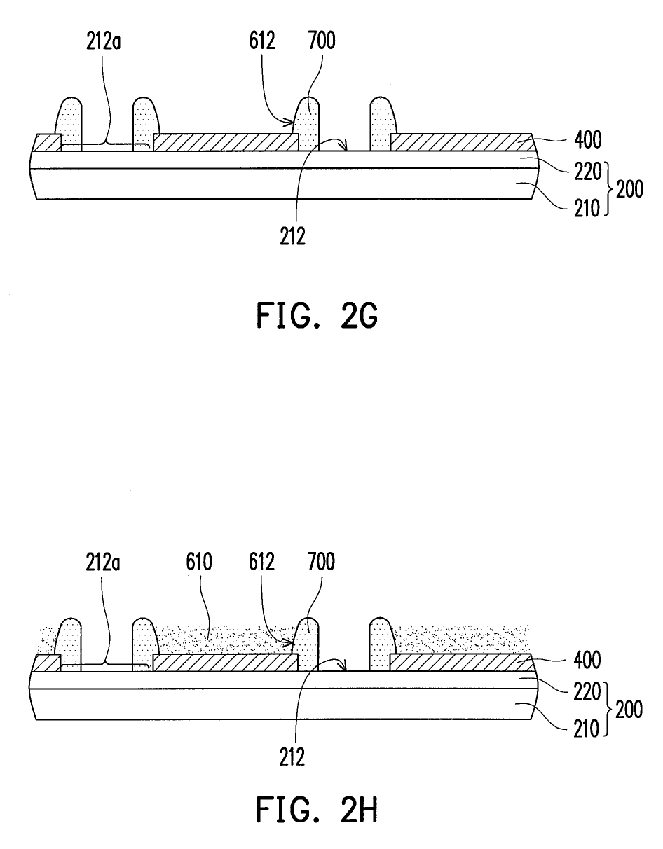

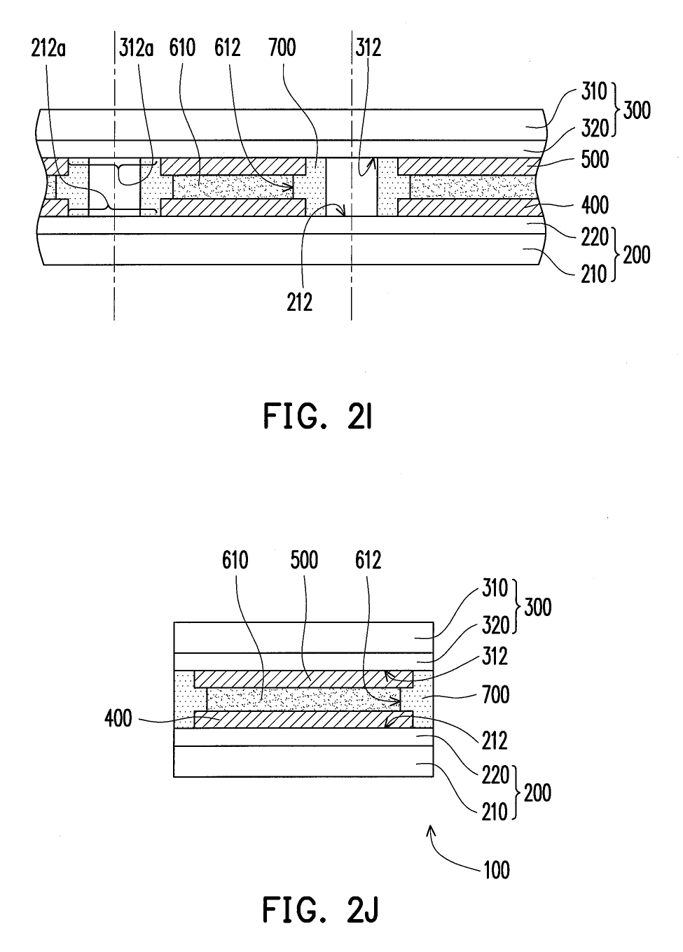

FIG. 2A through FIG. 2J are schematic cross-sectional views of a manufacturing method of an display device according to an embodiment of the present invention. In order to facilitate illustration, FIGS. 2A to 2C and FIGS. 2G to 2J omit illustrations of the active devices 214. Referring to FIG. 2A, according to a manufacturing method of the display device in the present embodiment, an active device array substrate 200 (i.e. a substrate) is first provided. Here, the active device array substrate 200 includes a silicon substrate 210 having an active surface 212 (i.e. an upper surface) and a pixel electrode 220. The pixel electrode 220 is disposed on the silicon substrate 210 and located at the active surface 212.

Next, referring to FIG. 2A, a first patterned photoresist layer 230 is formed on a first photoresist-disposed area 212a of the active surface 212 of the silicon substrate 210. Specifically, a first photoresist layer (not shown) is formed and covered the active surface 212 of the silicon substrate 210 firstly. Thereafter, the first patterned photoresist layer 230 is formed by an exposure process and a developing process.

Afterward, referring to FIG. 2B, a first alignment layer 410 is obliquely vapor-deposited on the active surface 212 and the first patterned photoresist layer 230. In the present embodiment, a first vapor-depositing source 800a is provided above the active device array substrate 200. Subsequently, the first alignment layer 410 is obliquely vapor-deposited on the active surface 212 and the first patterned photoresist layer 230 in a first vapor-depositing direction d1. Herein, the first vapor-depositing direction d1 tilts relative to the active surface 212. In this embodiment, the first vapor-depositing direction d1 and the active surface 212 have an included angle a1, and this included angle a1 is between 25 and 35 degrees. The active surface 212 has at least a first undeposited area 212b located beside an edge of the first patterned photoresist layer 230. The first alignment layer 410 does not cover the first undeposited area 212b. Particularly, in the present embodiment, the first alignment layer 410 is aligned while the oblique vapor-deposition is performed. A material of the first alignment layer 410 is, for example, silicon dioxide.

Moreover, referring to FIG. 2C, the first patterned photoresist layer 230 and a portion of the first alignment layer 410 located on the first patterned photoresist layer 230 are removed by using a first photoresist remover (not shown) to form at least a first alignment unit 400 (three units are shown in FIG. 2C for example) and expose the first photoresist-disposed area 212a. In specific, in the present embodiment, a lift off method is adopted, that is to soak the active device array substrate 200, the first patterned photoresist layer 230 formed thereon, and the first alignment layer 410 in the first photoresist remover. Consequently, the first photoresist remover removes the first patterned photoresist layer 230 and the first alignment layer 410 formed thereon to form the first alignment unit 400. Here, the first photoresist remover is acetone, for instance. Up to this point, the first alignment unit 400 has been formed on the active device array substrate 200 and the manufacture of an alignment substrate is completed.

In the manufacturing method of the alignment substrate of the present embodiment, the first alignment unit 400 is selectively formed on the active device array substrate 200, and the first alignment layer 410 is aligned simultaneously while being obliquely vapor-deposited. Therefore, the manufacturing steps are simplified to enhance an efficiency of the manufacturing method for manufacturing alignment substrates.

Subsequently, referring to FIG. 2D, an opposite substrate 300 (i.e. another substrate) is provided. The opposite substrate 300 includes a light transmissive substrate 310 and a light transmissive electrode 320. The light transmissive substrate 310 has a light transmissive surface 312 (i.e. another upper surface) and the light transmissive electrode 320 is disposed on the light transmissive substrate 310 and located at the light transmissive surface 312.

Next, referring to FIG. 2D, a second patterned photoresist layer 330 is formed on a second photoresist-disposed area 312a of the light transmissive surface 312. Specifically, a second photoresist layer (not shown) is formed and covered the light transmissive surface 312 firstly. Thereafter, the second patterned photoresist layer 330 is formed on the second photoresist-disposed area 312a of the light transmissive surface 312 by the exposure process and the developing process.

Afterward, referring to FIG. 2E, a second alignment layer 510 is obliquely vapor-deposited on the light transmissive surface 312 and the second patterned photoresist layer 330. As previously illustrated in FIG. 2B, the light transmissive surface 312 has at least a second undeposited area 312b located beside an edge of the second patterned photoresist layer 330. The second alignment layer 510 does not cover the second undeposited area 312b. In the present embodiment,a second vapor-depositing source 800b is provided on the opposite substrate 300. Subsequently, the second alignment layer 510 is obliquely vapor-deposited on the light transmissive surface 312 and the second patterned photoresist layer 330 in a second vapor-depositing direction d2. Herein, the second vapor-depositing direction d2 tilts relative to the light transmissive surface 312. In this embodiment, the second vapor-depositing direction d2 and the light transmissive surface 312 have an included angle a2, and this included angle a2 is between 25 and 35 degrees. Particularly, in the present embodiment, the second alignment layer 510 is aligned simultaneously while the oblique vapor-deposition is performed. A material of the second alignment layer 510 is, for example, silicon dioxide.

Furthermore, referring to FIG. 2F, the second patterned photoresist layer 330 and a portion of the second alignment layer 510 located on the second patterned photoresist layer 330 are removed from the second edge 332 by using a second photoresist remover (not shown) to form at least a second alignment unit 500 (three units are shown in FIG. 2F for example) and expose the second photoresist-disposed area 312a. As previously illustrated in FIG. 2C, the second alignment unit 500 has been formed on the opposite substrate 300 and the manufacture of another alignment substrate is completed.

Later, referring to FIG. 2G, at least a sealant 700 is directly formed on the active surface 212 of the active device array substrate 200 and surrounds the peripheral of the first alignment unit 400. The sealant 700 and the first alignment unit 400 form at least a containing recess 612 for filling liquid crystal. It should be illustrated that the location at which the sealant 700 has formed is not limited in the present invention. In the present embodiment, the sealant 700 is formed on the active device array substrate 200. However, in other embodiments, the sealant 700 may be directly formed on the light transmissive surface 312 of the opposite substrate 300 and surrounds the peripheral of the second alignment unit 500. Hence, the sealant 700 illustrated in FIG. 2G is merely exemplary and the present embodiment is not limited thereto.

Next, referring to FIG. 2H, a one-drop filling process is performed so as to fill a liquid crystal material 610 into the containing recess 612. Thereafter, referring to FIG. 2I, the active device array substrate 200 and the opposite substrate 300 are assembled for packing the liquid crystal material 610 therebetween, so that the active surface 212 and the light transmissive surface 312 face each other and the first alignment unit 400 aligns with the second alignment unit 500.

After the active device array substrate 200 and the opposite substrate 300 are assembled, referring to FIGS. 2I and 2J simultaneously, a cutting process is performed along the first photoresist-disposed area 212a and the second photoresist-disposed area 312a to form a plurality of display devices 100 (only one display device is shown in FIG. 2J for illustration). Then, the manufacture of the display device 100 is completed.

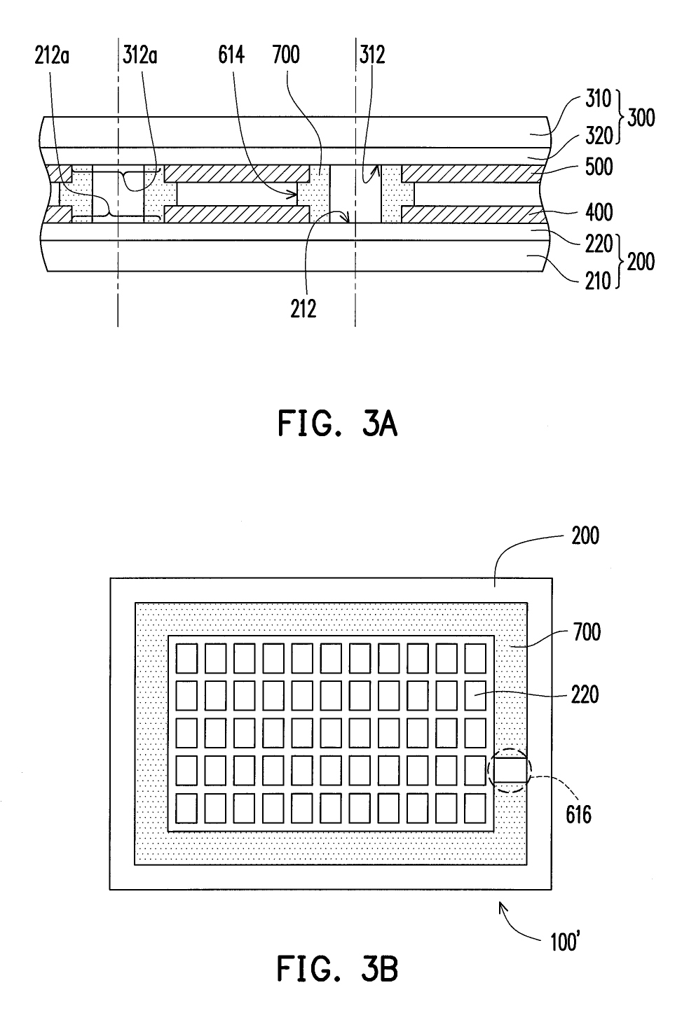

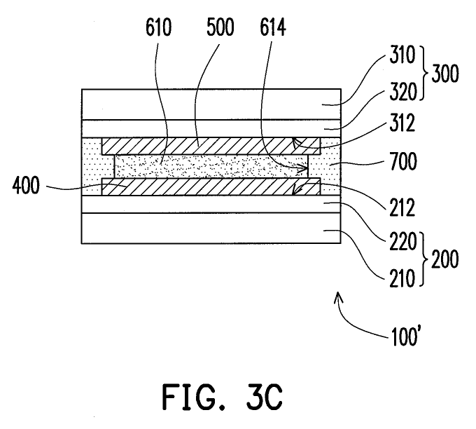

It should be noted that in the present embodiment, the liquid crystal material 610 is first filled into the containing recess 612, and then the active device array substrate 200 and the opposite substrate 300 are assembled and cut. However, in other embodiments, the active device array substrate 200 and the opposite substrate 300 are assembled before liquid crystal filling. Referring to FIG. 3A through 3C, the sealant 700, the first alignment unit 400, and the second alignment unit 500 form at least a liquid crystal containing space 614 (shown as a plurality of liquid crystal containing spaces in FIG. 3A) after assembling. The liquid crystal material 610 is injected into the liquid crystal containing space 614 via a liquid crystal injection entrance 616 preserved in the formation of the sealant 700. Afterwards, a cutting process is performed to forming a plurality of display devices 100′.

In summary, in the manufacturing method of the alignment substrate of the embodiment in the present invention, the formation of the patterned photoresist layer is incorporated with the oblique vapor-deposition to form the alignment units. Then, the alignment units are selectively formed on the substrate. In addition, the alignment layers are aligned simultaneously while the alignment layers are obliquely vapor-deposited, thereby simplifying the manufacturing steps. Furthermore, in the manufacturing method of the display device of the present embodiment, the alignment units on the active device array substrate and the opposite substrate are manufactured by using the photoresist remover. Afterwards, the sealant is disposed on the active device array substrate and the opposite substrate and surrounds the liquid crystal layer and the alignment units for assembling the opposite substrate with the active device array substrate. As a consequence, not only is the conventional problem of moisture invading into the liquid crystal layer via the alignment layer prevented, but the manufacturing yield rate is also enhanced. Hence, the display device of the embodiment in the present invention has superior display quality.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A manufacturing method of a display device, comprising:
providing an active device array substrate having an active surface;
forming a first patterned photoresist layer on the active surface;
obliquely vapor-depositing a first alignment layer on the active surface and the first patterned photoresist layer, wherein the active surface comprises at least a first undeposited area located beside an edge of the first patterned photoresist layer;
removing the first patterned photoresist layer and a portion of the first alignment layer located thereon to form a first alignment unit;
directly forming a sealant on the active surface of the active device array substrate and surrounding the first alignment unit;
providing an opposite substrate having a light transmissive surface; and
assembling the active device array substrate and the opposite substrate.

2. The manufacturing method of the display device as claimed in claim 1, further comprising:
forming a second patterned photoresist layer on the light transmissive surface;
obliquely vapor-depositing a second alignment layer on the light transmissive surface and the second patterned photoresist layer, wherein the light transmissive surface comprises at least a second undeposited area located beside an edge of the second patterned photoresist layer; and
removing the second patterned photoresist layer and a portion of the second alignment layer thereon to form a second alignment unit.

3. The manufacturing method of the display device as claimed in claim 2, further comprising:
directly forming a sealant on the light transmissive surface of the opposite substrate and surrounding the second alignment unit.

4. The manufacturing method of the display device as claimed in claim 3, further comprising:
connecting the active device array substrate with the opposite substrate via the sealants and aligning the first alignment unit with the second alignment unit.

5. The manufacturing method of the display device as claimed in claim 1, wherein in the oblique vapor-depositing step further comprises:
providing a first vapor-depositing source above the active device array substrate; and
obliquely vapor-depositing the first alignment layer in a first vapor-depositing direction, wherein the first vapor-depositing direction tilts relative to the active surface.

6. The manufacturing method of the display device as claimed in claim 5, wherein an included angle between the first vapor-depositing direction and the active surface is between 25 and 35 degrees.

7. A display device, comprising:
an active device array substrate having an active surface;
an opposite substrate, disposed above the active device array substrate and having a light transmissive surface, wherein the active surface and the light transmissive surface face each other;
at least one first alignment unit, disposed on the active device array substrate and located on the active surface;
at least one second alignment unit, disposed on the opposite substrate and located on the light transmissive surface, wherein the first alignment unit aligns with the second alignment unit;
a liquid crystal layer, disposed between the first alignment unit and the second alignment unit; and
a sealant, directly connecting the active surface of the active device array substrate and the light transmissive surface of the opposite substrate, and surrounding peripherals of the liquid crystal layer, the first alignment unit, and the second alignment unit.

8. The display device as claimed in claim 7, wherein the active device array substrate comprises a silicon substrate and a pixel electrode, and the pixel electrode is disposed on the silicon substrate and located at the active surface.

9. The display device as claimed in claim 7, wherein the opposite substrate comprises a light transmissive substrate and a transparent electrode, and the transparent electrode is disposed on the light transmissive substrate and located at the light transmissive surface.
